(19) United States
(12) Patent Application Publication
(10) Pub. No.: US 2026/0276843 A1
(43) Pub. Date: Sep. 17, 2026

(54) X-RAY DETECTOR FOR NON-DESTRUCTIVE INSPECTION

(71) Applicant: LG ELECTRONICS INC., Seoul (KR)

(72) Inventors: Sungeun LEE, Seoul (KR); Youngjun JUNG, Seoul (KR); Byungkee LEE, Seoul (KR)

(73) Assignee: LG ELECTRONICS INC., Seoul (KR)

(21) Appl. No.: 19/472,998

(22) PCT Filed: Apr. 7, 2023
(86) PCT No.: PCT/KR2023/004758

§ 371 Date: Oct. 6, 2025

(51) Int. Cl. G01T 1/20; G01N 23/04; G01N 23/083

(52) U.S. Cl. CPC G01T 1/2018; G01N 23/04; G01N 23/083; G01N 2223/628

(57) ABSTRACT

The present invention relates to an x-ray detector for non-destructive inspection, comprising: a scintillator for converting incident x-rays into visible light; a photoelectric converter disposed under the scintillator film to convert the visible light into electrical signals; a lead-free x-ray-absorbing film disposed under the photoelectric converter; a flexible magnetic sheet disposed under the lead-free x-ray-absorbing film.

### TECHNICAL FIELD

The present disclosure relates to an X-ray detector for non-destructive inspection.

### BACKGROUND ART

Representative scintillator materials currently used in a commercial X-ray detector are CsI(Tl) and Gd2O2S:Tb(Gadox), and are mostly formed in a rigid layered structure.

A material of CsI(Tl) has an advantage of high light emission for X-rays and excellent quantum detection efficiency of an optical sensor coupled thereto because a wavelength of visible light emitted by the doped Tl component is 550 nm.

However, since the material of CsI(Tl) exists in a crystalline state, the crystals break when bent so as to sharply reduce efficiency, and it is expensive because it is manufactured using thermal deposition equipment.

Therefore, an indirect X-ray detector is required to maintain high resolution and spatial resolution without image spreading or blurring due to light scattering by a scintillator, and a freely bendable scintillator film that satisfies X-ray energy and spatial resolution suitable for the application field to be used is required.

In addition, when capturing an image of a curved object using a rigid X-ray detector (e.g., pipe inspection), there is a disadvantage in that it is difficult to acquire an image while the detector is in close contact along a curved surface of the pipe because it is a flat plate, and a separate element for attaching the detector is required.

From the perspective of image implementation, focusing is limited to a small area in the center due to the flat surface, so the X-ray irradiation field becomes narrow, and when X-rays are irradiated to an entire surface of the detector, distortion occurs in the obtained image due to a difference in distance between the center and the edge. Additionally, in order to capture an entire circumference of the pipe, there is a disadvantage in that it requires repeated capturing while rotating 360 degrees and then reconstructing the image.

Recently, curved X-ray detectors for pipe inspection have been developed, but since they are mechanically bent at a predetermined angle, the apparatuses are bulky, and since they are disposed closely to the pipe through a separate device rather than a direct attachment method to the pipe, they are not useful in terms of handling as well as usability.

### DISCLOSURE OF INVENTION

### Technical Problem

An aspect of the present disclosure is to provide an X-ray detector for non-destructive inspection that can acquire a clear image without image distortion.

Another aspect of the present disclosure is to provide an X-ray detector for non-destructive inspection that can perform inspection on a curved inspection body in an optimized manner using a flexible material.

Still another aspect of the present disclosure is to provide an X-ray detector for non-destructive inspection that can be attached to a curved inspection body in close contact therewith without a separate fixing device to perform inspection.

### Solution to Problem

In order to achieve the foregoing or other objectives, according to an aspect of the present disclosure, an X-ray detector for non-destructive inspection may include a scintillator that converts incident X-rays into visible light, a photoelectric converter disposed below the scintillator film to convert the visible light into an electrical signal, a lead-free X-ray absorption film disposed below the photoelectric converter, and a flexible magnetic sheet disposed below the lead-free X-ray absorption film.

In an embodiment, the scintillator may include a perovskite compound.

In an embodiment, the scintillator, the photoelectric converter, the lead-free X-ray absorption film, and the magnetic sheet may be formed to be bent.

In an embodiment, the X-ray detector may be allowed to be attached in close contact with an inspection body through the flexible magnetic sheet.

In an embodiment, the X-ray detector may be attached to the inspection body through a magnetic sheet without a fixing structure.

In an embodiment, the inspection body may include a pipe having a curved surface.

In an embodiment, the X-ray detector may be allowed to be attached in close contact with the inspection body even if the inspection body has an arbitrary radius of curvature.

In an embodiment, the X-ray detector may further include a reflective layer disposed above the scintillator to reflect the visible light to a photoelectric converter disposed below.

In an embodiment, the X-ray detector may further include a flexible substrate disposed above the reflective layer.

In an embodiment, the scintillator may include a perovskite compound represented by [Formula 1].

A₃B₂X₅:Activator [Formula 1]

(In the Formula 1, A is a monovalent metal cation, B is a divalent metal cation, X comprises a monovalent anion, and the activator is Tl or In.)

In an embodiment, the A may include at least one selected from a group consisting of Li⁺, Na⁺, K⁺, Rb⁺, Cs⁺ and Au(I)⁺.

In an embodiment, the B may include at least one selected from a group consisting of Sn²⁺, Ge²⁺, Cu²⁺, Co²⁺, Ni²⁺, Ti²⁺, Zr²⁺, Hf²⁺ and Rf²⁺.

In an embodiment, the X may include at least one selected from a group consisting of F⁻, Cl⁻, Br⁻, I⁻, SCN⁻ and BF₄⁻.

In an embodiment, the activator may include at least one selected from a group consisting of Tl (thallium) and In.

In an embodiment, the perovskite compound may include nanocrystalline particles.

In an embodiment, a particle size of the nanocrystalline particles may be in a range of from 1 nm to 950 nm.

In an embodiment, the scintillator may further include an organic binder.

In an embodiment, the organic binder may include at least one selected from a group consisting of polydimethyl siloxane resin, acrylic resin, ether resin, polyvinyl acetate resin, polystyrene resin, polycarbonate resin, polyamide resin, and polyurethane resin.

In an embodiment, the scintillator may include a perovskite compound and an organic binder in a weight ratio of 90:10 or 10:90.

In an embodiment, a thickness of the scintillator may be in a range of from 1 um to 1,000 um.

In an embodiment, the photoelectric converter may include at least one of a silicon photodiode, a complementary metal oxide semiconductor, and an organic photodiode.

In an embodiment, the lead-free X-ray absorption film may include at least one of absorption compounds in [Formula 2] below.

BaSO₄, W, Bi, Sn, Cu, Ti, Gd₂O₃, WO₃, Er₂O₃, Bi₂O₃ [Formula 2]

In an embodiment, the absorption compound may include nanocrystalline particles.

In an embodiment, a particle size of the nanocrystalline particles may be in a range of from 1 nm to 950 nm.

In an embodiment, the lead-free X-ray absorption film may further include an organic binder.

In an embodiment, the organic binder may include at least one selected from a group consisting of polydimethyl siloxane resin, acrylic resin, ether resin, polyvinyl acetate resin, polystyrene resin, polycarbonate resin, polyamide resin, and polyurethane resin.

In an embodiment, the lead-free X-ray absorption film may include an absorption compound and an organic binder in a weight ratio of 10:70 or 70:10.

In an embodiment, a thickness of the lead-free X-ray absorption film may be in a range of from 0.5 mm to 5 mm.

In an embodiment, the magnetic sheet may include at least one magnetic material compound represented by [Formula 3] below.

SrCO3, 6Fe2O3, AlNiCo, SmCo5, Sm2Co17, Nd—Fe—B [Formula 3]

In an embodiment, the magnetic material compound may include nanocrystalline particles.

In an embodiment, a particle size of the nanocrystalline particles may be in a range of from 1 nm to 950 nm.

In an embodiment, the magnetic sheet may further include an organic binder.

In an embodiment, the organic binder may include at least one selected from a group consisting of polydimethyl siloxane resin, acrylic resin, ether resin, polyvinyl acetate resin, polystyrene resin, polycarbonate resin, polyamide resin, and polyurethane resin.

In an embodiment, the magnetic sheet may include a magnetic material compound and the organic binder in a weight ratio of 70:10 or 10:70.

In an embodiment, a thickness of the magnetic sheet may be in a range of from 0.5 mm to 5 mm.

### Advantageous Effects of Invention

According to the present disclosure, a perovskite quantum dot compound may be used as a scintillator material in the present disclosure so as to allow a manufacturing process of an X-ray detector to be simple and reduce the manufacturing cost, and may have both advantages of an organic material and an inorganic material, thereby facilitating thick film manufacturing, high reproducibility, and excellent durability.

In addition, due to a fast response speed of the perovskite compound, it may have excellent sensitivity to X-rays, absorption characteristics, and time resolution, and low resistance characteristics so as to be implemented in a flexible film form, thereby having an advantage of being able to bend into a desired shape without damaging the film when bent.

A flexible X-ray detector of the present disclosure may easily acquire a desired image in real time while the detector is in close contact along a curved surface of a pipe when capturing an image a curved object (e.g., pipe inspection) and have a magnetic sheet so as to have an advantage of allowing a magnetic attachment to a surface of an object to be measured without a separate element for attaching the detector.

From the perspective of image implementation, an image may be obtained in a form that is closely related to the shape so as to allow an image to be acquired for an entire surface, and a distance between the center and the edge may be maintained constant, thereby having an advantage in that there is no distortion in the obtained image. Additionally, a number of shots required to capture an entire circumference of the pipe may be drastically reduced.

Compared to the recently developed curved X-ray detectors, there is no need for a separate mechanical device and a separate power supply apparatus, and the flexible X-ray detector itself is attached directly to the pipe, thereby having a useful advantage in terms of handling as well as usability.

### BRIEF DESCRIPTION OF DRAWINGS

FIGS. 1 and 2 are conceptual diagrams for explaining a conventional X-ray detector.

FIGS. 3 and 4 are conceptual diagrams for explaining an X-ray detector according to the present disclosure.

FIG. 5 is a conceptual diagram for explaining image distortion output through a conventional X-ray detector.

FIG. 6 is a conceptual diagram for explaining image distortion output through an X-ray detector according to the present disclosure.

### MODE FOR THE INVENTION

It should be noted that technical terms used herein are merely used to describe a specific embodiment, but are not intended to limit the present disclosure. In addition, a singular expression used herein may include a plural expression unless clearly defined otherwise in the context. A suffix “module” or “part” used for elements disclosed in the following description is merely intended for easy description of the specification, and the suffix itself is not intended to have any special meaning or function.

As used herein, terms such as “comprise” or “include” should not be construed to necessarily include all elements or steps described herein, and should be construed not to include some elements or some steps thereof, or should be construed to further include additional elements or steps.

In addition, in describing technologies disclosed herein, when it is determined that a detailed description of known technologies related thereto may unnecessarily obscure the subject matter disclosed herein, the detailed description will be omitted.

In addition, the accompanying drawings are provided only for a better understanding of the embodiments disclosed in this specification and are not intended to limit technical concepts disclosed in this specification, and therefore, it should be understood that the accompanying drawings include all modifications, equivalents and substitutes within the concept and technical scope of the present disclosure. In addition, not only individual embodiments described below but also a combination of the embodiments may, of course, fall within the concept and technical scope of the present disclosure, as modifications, equivalents or substitutes included in the concept and technical scope of the present disclosure.

Hereinafter, the configuration and operation of the present disclosure will be described in more detail with reference to a number of drawings related to the present disclosure.

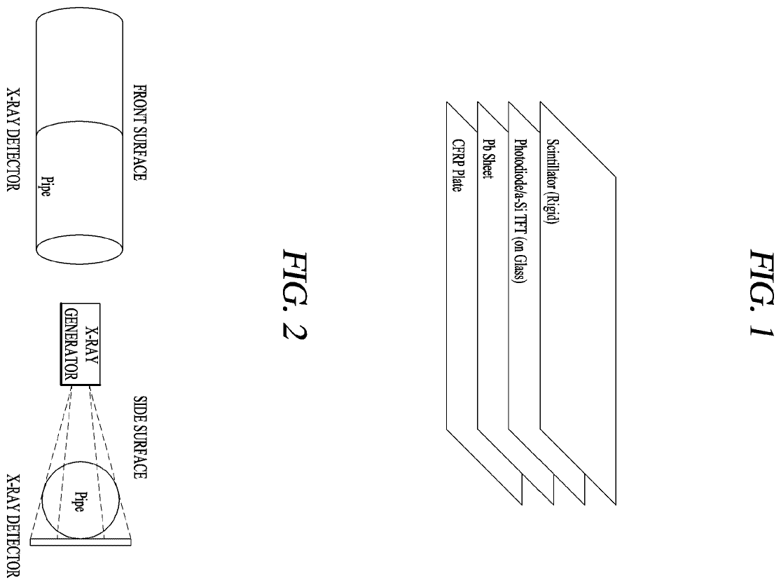

FIGS. 1 and 2 are conceptual diagrams for explaining a conventional X-ray detector.

Referring to FIG. 1, the conventional X-ray detector includes a scintillator, a photodiode formed on a glass substrate, a Pb sheet, and a CFRP plate.

Such an X-ray detector cannot be bent, and when it is forcibly bent by an external force, the X-ray detector is destroyed.

Accordingly, the conventional X-ray detector is not flexible, and is formed in a flat, rigid shape.

Referring to FIG. 2, when performing pipe inspection using such a flat and rigid X-ray detector, there is a disadvantage in that it is difficult to acquire an image while being in close contact along a curved surface of the pipe because it is flat, and a separate element for attaching the detector is required.

Recently, curved X-ray detectors for pipe inspection have been developed, but since they are mechanically bent at a predetermined angle, the apparatuses are bulky, and since they are disposed closely to the pipe through a separate device rather than a direct attachment method to the pipe, they are not useful in terms of handling as well as usability.

Even in the obtained image plane, since an image limited to a narrow area is obtained from a flat detector, there is an inconvenience in that in order to obtain a 360-degree image, the X-ray generator and detector must be rotated 360 degrees to obtain and edit an image of a required area.

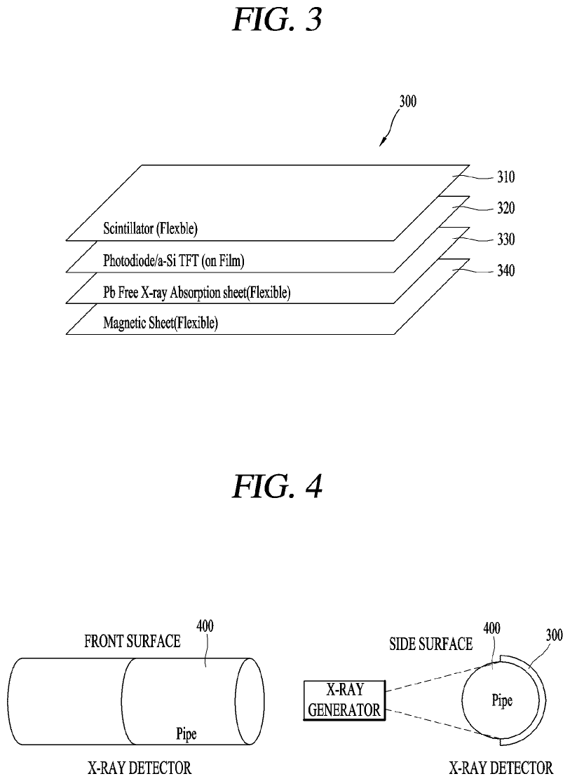

FIGS. 3 and 4 are conceptual diagrams for explaining an X-ray detector according to the present disclosure.

Referring to FIG. 3, a non-destructive inspection X-ray detector 300 of the present disclosure includes a scintillator (flexible) 310 that converts incident X-rays into visible light, a photoelectric converter (photodiode/a-Si TFT (on film)) 320 disposed below the scintillator film to convert the visible light into an electrical signal, a lead-free X-ray absorption film (Pb-free X-ray absorption sheet (flexible)) 330 disposed below the photoelectric converter, and a flexible magnetic sheet (flexible) 340 disposed below the lead-free X-ray absorption film.

The non-destructive inspection X-ray detector 300 of the present disclosure has the scintillator film 310 including a perovskite compound formed above the photoelectric converter 320 having a plurality of pixels such as a photodiode, and the lead-free X-ray absorption film 330 and the magnetic sheet 340 provided on a rear surface of the photoelectric converter 320, thereby forming a layered structure that can be directly attached to a metal surface by a magnetic force while being flexible.

The layered structure may form various orders of layered structures for each application field. That is, depending on an attachment surface, the magnetic sheet may be layered on an entire surface above the scintillator film.

The scintillator 310 includes a perovskite compound.

In addition, the scintillator 310, the photoelectric converter 320, the lead-free X-ray absorption film 330, and the magnetic sheet 340 may be formed to be flexible (curved).

Referring to FIG. 4, the non-destructive inspection X-ray detector 300 may be attached to an inspection body 400 in close contact with the flexible magnetic sheet.

The non-destructive inspection X-ray detector 300 may be attached to the inspection body 400 through a magnetic sheet without a fixing structure. The attachment may be implemented by using the magnetic sheet 340.

The inspection body 400 may include a pipe having a curved surface.

Referring to FIG. 4, the non-destructive inspection X-ray detector 300 may be attached in close contact with the inspection body 400 having an arbitrary radius of curvature so as to acquire an image without image distortion.

Meanwhile, although not shown, the non-destructive inspection X-ray detector 300 may further include a reflective layer disposed above the scintillator 310 to reflect the visible light to a photoelectric converter disposed below.

Additionally, the non-destructive inspection X-ray detector 300 may further include a flexible substrate disposed above the reflective layer.

Meanwhile, the scintillator 310 includes a perovskite compound represented by [Formula 1].

A₃B₂X₅:Activator [Formula 1]

Here, A may be a monovalent metal cation, B may be a divalent metal cation, X may include a monovalent anion, and the activator may be Tl or In.

The A may include at least one selected from a group consisting of Li⁺, Na⁺, K⁺, Rb⁺, Cs⁺ and Au(I)⁺.

The B may include at least one selected from a group consisting of Sn²⁺, Ge²⁺, Cu²⁺, Co²⁺, Ni²⁺, Ti²⁺, Zr²⁺, Hf²⁺ and Rf²⁺.

The X may include at least one selected from a group consisting of F⁻, Cl⁻, Br⁻, I⁻, SCN⁻ and BF₄⁻.

The activator may include at least one selected from a group consisting of Tl (thallium) and In.

The perovskite compound may include nanocrystalline particles, and a particle size of the nanocrystalline particles may be in a range of from 1 nm to 950 nm.

The scintillator may further include an organic binder. The organic binder included in the scintillator may be a first organic binder. The organic binder includes at least one selected from a group consisting of polydimethyl siloxane resin, acrylic resin, ether resin, polyvinyl acetate resin, polystyrene resin, polycarbonate resin, polyamide resin, and polyurethane resin.

The scintillator may include a perovskite compound and an organic binder in a weight ratio of 90:10 or 10:90.

Additionally, a thickness of the scintillator may be in a range of from 1 um to 1,000 um.

The photoelectric converter 320 may include at least one of a silicon photodiode, a complementary metal oxide semiconductor, and an organic photodiode.

Meanwhile, the lead-free X-ray absorption film 330 (or lead-free shielding film) may include at least one of absorption compounds in [Formula 2] below.

BaSO₄, W, Bi, Sn, Cu, Ti, Gd₂O₃, WO₃, Er₂O₃, Bi₂O₃ [Formula 2]

The absorption compound may include nanocrystalline particles, and a particle size of the nanocrystalline particles may be in a range of from 1 nm to 950 nm.

The lead-free X-ray absorption film may include an organic binder.

Here, the organic binder included in the lead-free X-ray absorption film may be a second organic binder.

The organic binder may include at least one selected from a group consisting of polydimethyl siloxane resin, acrylic resin, ether resin, polyvinyl acetate resin, polystyrene resin, polycarbonate resin, polyamide resin, and polyurethane resin.

The lead-free X-ray absorption film may include an absorption compound and an organic binder in a weight ratio of 10:70 or 70:10.

A thickness of the lead-free X-ray absorption film may be in a range of from 0.5 mm to 5 mm.

Meanwhile, the magnetic sheet may include at least one magnetic material compound represented by [Formula 3] below.

SrCO₃, 6Fe₂O₃, AlNiCo, SmCo₅, Sm₂Co₁₇, Nd—Fe—B [Formula 3]

The magnetic material compound may include nanocrystalline particles, and a particle size of the nanocrystalline particles may be in a range of from 1 nm to 950 nm.

The magnetic sheet may further include an organic binder, and the organic binder included in the magnetic sheet may be a third organic binder. The organic binder may include at least one selected from a group consisting of polydimethyl siloxane resin, acrylic resin, ether resin, polyvinyl acetate resin, polystyrene resin, polycarbonate resin, polyamide resin, and polyurethane resin.

The magnetic sheet may include a magnetic material compound and the organic binder in a weight ratio of 70:10 or 10:70.

A thickness of the magnetic sheet may be in a range of from 0.5 mm to 5 mm.

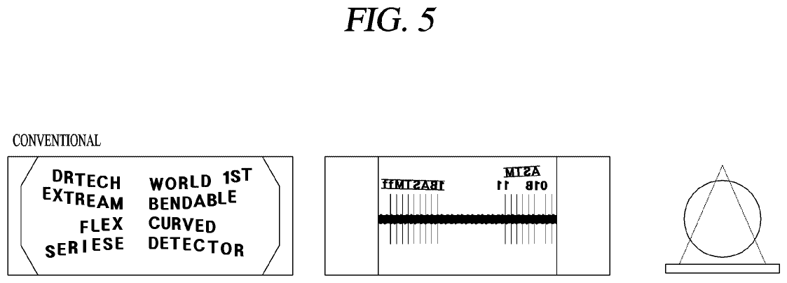

FIG. 5 is a conceptual diagram for explaining image distortion output through a conventional X-ray detector.

Referring to FIGS. 3 and 5, the conventional X-ray detector is formed in a flat plate shape due to a rigid material and layered structure configuration, and a flat plate-shaped X-ray detector fixing structure is separately required.

In addition, the conventional X-ray detector has a narrow X-ray irradiation angle because the focusing portion is limited to a small area due to the flat plate. Accordingly, when the conventional X-ray detector irradiates an entire surface of the detector, image distortion occurs due to a difference in distance between the center and the edge.

Additionally, the conventional X-ray detector requires repeated capturing while rotating 360 degrees and then reconstructing the image in order to irradiate an entire circumference of the pipe.

In addition, an existing scintillator composition, a material of CsI(Tl), has an advantage of high light emission for X-rays and excellent quantum detection efficiency of an optical sensor coupled thereto because a wavelength of visible light emitted by the doped Tl component is 550 nm, but since the material of CsI(Tl) exists in a crystalline state, the crystals break when bent so as to sharply reduce efficiency, and it is expensive because it is manufactured using thermal deposition equipment.

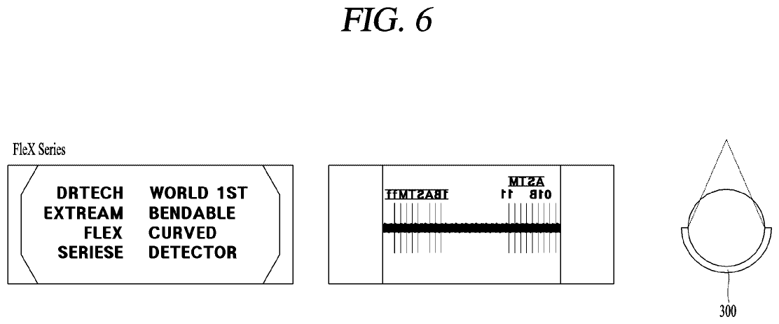

FIG. 6 is a conceptual diagram for explaining image distortion output through an X-ray detector according to the present disclosure.

Referring to FIGS. 4 and 6, the non-destructive inspection X-ray detector 300 of the present disclosure may be formed in a flexible shape due to a flexible material application layered structure configuration, and a separate X-ray detector fixing structure is not required due to the magnetic sheet.

In addition, the non-destructive inspection X-ray detector 300 of the present disclosure has a wide X-ray irradiation angle (or irradiation field) because the focusing portion corresponds to an entire area due to the close attachment to the shape of the pipe.

The non-destructive inspection X-ray detector 300 of the present disclosure may easily reconstruct an image by 2 to 3 repeated rotational capturing depending on an angle in order to irradiate an entire circumference of the pipe.

The non-destructive inspection X-ray detector 300 of the present disclosure is advantageous in implementing high robustness and high resolution required for industrial use by applying a perovskite scintillator composition based on quantum dots (QDs), and also has an advantage of being low in price because it is manufactured through a printing process by utilizing quantum dot ink.

Besides, the non-destructive inspection X-ray detector 300 of the present disclosure may directly read a clear image without image distortion at the inspection site even for a inspection body having any radius of curvature.

In summary, when utilizing the flexible X-ray detector structure of the present disclosure, it may be bent along a curve of the pipe so as to acquire an image while being in close contact with a curved surface, and it may have a magnetic sheet that can be attached to the pipe so as not to require a separate element to attach the detector.

In addition, in the case of a scintillator composition thallium doped cesium copper iodide obtained through a quantum dot synthesis in the present disclosure, it may be implemented and attached in a form of a separate film or may be implemented by directly applying it through printing on a photodiode on a-Si TFT in order to be applied to a large-area digital X-ray detector.

In addition, the present disclosure has a flexible lead-free X-ray absorption sheet so as to have an advantage that can remove noise caused by rear X-ray scattering, and has a magnetic sheet on the outermost surface so as to have an advantage that can be magnetically attached to a metal pipe or the like.

According to the present disclosure, a perovskite quantum dot compound may be used as a scintillator material in the present disclosure so as to allow a manufacturing process of an X-ray detector to be simple and reduce the manufacturing cost, and may have both advantages of an organic material and an inorganic material, thereby facilitating thick film manufacturing, high reproducibility, and excellent durability.

In addition, due to a fast response speed of the perovskite compound, it may have excellent sensitivity to X-rays, absorption characteristics, and time resolution, and low resistance characteristics so as to be implemented in a flexible film form, thereby having an advantage of being able to bend into a desired shape without damaging the film when bent.

A flexible X-ray detector of the present disclosure may easily acquire a desired image in real time while the detector is in close contact along a curved surface of a pipe when capturing an image a curved object (e.g., pipe inspection) and have a magnetic sheet so as to have an advantage of allowing a magnetic attachment to a surface of an object to be measured without a separate element for attaching the detector.

From the perspective of image implementation, an image may be obtained in a form that is closely related to the shape so as to allow an image to be acquired for an entire surface, and a distance between the center and the edge may be maintained constant, thereby having an advantage in that there is no distortion in the obtained image. Additionally, a number of shots required to capture an entire circumference of the pipe may be drastically reduced.

Compared to the recently developed curved X-ray detectors, there is no need for a separate mechanical device and a separate power supply apparatus, and the flexible X-ray detector itself is attached directly to the pipe, thereby having a useful advantage in terms of handling as well as usability.

Therefore, the detailed description should not be limitedly construed in all of the aspects, and should be understood to be illustrative. The scope of the present disclosure should be determined by reasonable interpretation of the appended claims, and all changes that come within the equivalent scope of the present disclosure are included in the scope of the present disclosure.

What is claimed is:

1. An X-ray detector for non-destructive inspection, the X-ray detector comprising:
a scintillator that converts incident X-rays into visible light;
a photoelectric converter disposed below the scintillator film to convert the visible light into an electrical signal;
a lead-free X-ray absorption film disposed below the photoelectric converter; and
a flexible magnetic sheet disposed below the lead-free X-ray absorption film.

2. The X-ray detector of claim 1, wherein the scintillator comprises:
a perovskite compound.

3. The X-ray detector of claim 1, wherein the scintillator, the photoelectric converter, the lead-free X-ray absorption film, and the magnetic sheet are formed to be bent.

4. The X-ray detector of claim 3, wherein the X-ray detector is allowed to be attached in close contact with an inspection body through the flexible magnetic sheet.

5. The X-ray detector of claim 4, wherein the X-ray detector is attached to the inspection body through a magnetic sheet without a fixing structure.

6. The X-ray detector of claim 4, wherein the inspection body comprises a pipe having a curved surface.

7. The X-ray detector of claim 4, wherein the X-ray detector is allowed to be attached in close contact with the inspection body even if the inspection body has an arbitrary radius of curvature.

8. The X-ray detector of claim 1, further comprising:
a reflective layer disposed above the scintillator to reflect the visible light to a photoelectric converter disposed below.

9. The X-ray detector of claim 8, further comprising:
a flexible substrate disposed above the reflective layer.

10. The X-ray detector of claim 2, wherein the scintillator comprises a perovskite compound represented by [Formula 1].
A₃B₂X₅:Activator [Formula 1]
(In the Formula 1, A is a monovalent metal cation, B is a divalent metal cation, X comprises a monovalent anion, and the activator is Tl or In).

11. The X-ray detector of claim 10, wherein the A comprises at least one selected from a group consisting of Li⁺, Na⁺, K⁺, Rb⁺, Cs⁺ and Au(I)⁺.

12. The X-ray detector of claim 10, wherein the B comprises at least one selected from a group consisting of Sn²⁺, Ge²⁺, Cu²⁺, Co²⁺, Ni²⁺, Ti²⁺, Zr²⁺, Hf²⁺ and Rf²⁺.

13. The X-ray detector of claim 10, wherein the X comprises at least one selected from a group consisting of F⁻, Cl⁻, Br⁻, I⁻, SCN⁻ and BF₄⁻.

14. The X-ray detector of claim 10, wherein the activator comprises at least one selected from a group consisting of Tl (thallium) and In.

15. The X-ray detector of claim 2, wherein the perovskite compound comprises nanocrystalline particles.

16. The X-ray detector of claim 15, wherein a particle size of the nanocrystalline particles is in a range of from 1 nm to 950 nm.

17. The X-ray detector of claim 1, wherein the scintillator further comprises an organic binder.

18. The X-ray detector of claim 17, wherein the organic binder comprises at least one selected from a group consisting of polydimethyl siloxane resin, acrylic resin, ether resin, polyvinyl acetate resin, polystyrene resin, polycarbonate resin, polyamide resin, and polyurethane resin.

19. The X-ray detector of claim 1, wherein the scintillator comprises a perovskite compound and an organic binder in a weight ratio of 90:10 or 10:90.

20. The X-ray detector of claim 1, wherein a thickness of the scintillator is in a range of from 1 um to 1,000 um.

21. The X-ray detector of claim 1, wherein the photoelectric converter comprises at least one of a silicon photodiode, a complementary metal oxide semiconductor, and an organic photodiode.

22. The X-ray detector of claim 1, wherein the lead-free X-ray absorption film comprises at least one of absorption compounds in [Formula 2] below.
BaSO₄, W, Bi, Sn, Cu, Ti, Gd₂O₃, WO₃, Er₂O₃, Bi₂O₃ [Formula 2].

23. The X-ray detector of claim 22, wherein the absorption compound comprises nanocrystalline particles.

24. The X-ray detector of claim 23, wherein a particle size of the nanocrystalline particles is in a range of from 1 nm to 950 nm.

25. The X-ray detector of claim 1, wherein the lead-free X-ray absorption film further comprises an organic binder.

26. The X-ray detector of claim 25, wherein the organic binder comprises at least one selected from a group consisting of polydimethyl siloxane resin, acrylic resin, ether resin, polyvinyl acetate resin, polystyrene resin, polycarbonate resin, polyamide resin, and polyurethane resin.

27. The X-ray detector of claim 22, wherein the lead-free X-ray absorption film comprises an absorption compound and an organic binder in a weight ratio of 10:70 or 70:10.

28. The X-ray detector of claim 1, wherein a thickness of the lead-free X-ray absorption film is in a range of from 0.5 mm to 5 mm.

29. The X-ray detector of claim 1, wherein the magnetic sheet comprises at least one magnetic material compound represented by [Formula 3] below.
SrCO₃, 6Fe₂O₃, AlNiCo, SmCo₅, Sm₂Co₁₇, Nd—Fe—B [Formula 3].

30. The X-ray detector of claim 29, wherein the magnetic material compound comprises nanocrystalline particles.

31. The X-ray detector of claim 30, wherein a particle size of the nanocrystalline particles is in a range of from 1 nm to 950 nm.

32. The X-ray detector of claim 1, wherein the magnetic sheet further comprises an organic binder.

33. The X-ray detector of claim 30, wherein the organic binder comprises at least one selected from a group consisting of polydimethyl siloxane resin, acrylic resin, ether resin, polyvinyl acetate resin, polystyrene resin, polycarbonate resin, polyamide resin, and polyurethane resin.

34. The X-ray detector of claim 1, wherein the magnetic sheet comprises a magnetic material compound and the organic binder in a weight ratio of 70:10 or 10:70.

35. The X-ray detector of claim 1, wherein a thickness of the magnetic sheet is in a range of from 0.5 mm to 5 mm.
